(19) United States
(12) Patent Application Publication
(10) Pub. No.: US 2006/0142520 A1
(43) Pub. Date: Jun. 29, 2006

(54) Hole transport layers for organic electroluminescent devices

(75) Inventors: Todd D. Jones, St. Paul, MN (US); Sergey A. Lamansky, Apple Valley, MN (US); Tommie W. Kelley, Shoreview, MN (US); Kevin M. Lewandowski, Inver Grove Heights, MN (US); Fred B. McCormick, Maplewood, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 11/023,141

(22) Filed: Dec. 27, 2004

(51) Int. Cl. C08F 212/02; C08F 226/00; H01L 51/54; B32B 15/082; H05B 33/14

(52) U.S. Cl. 526/328.5; 428/690; 428/917; 428/500; 428/461; 313/504; 313/506; 257/40; 257/E51.033; 526/259; 526/310; 427/66

(57) ABSTRACT

A copolymeric material is described that is suitable for use in a hole transport layer of organic electroluminescent device. The copolymeric material contains a phosphorous-containing group selected from a phosphate or phosphonate group and tertiary amino group selected from a triarylamino group or carbazolyl group.

### TECHNICAL FIELD

A copolymeric material is provided that contains a phosphorous-containing group and a tertiary amino group. Organic electroluminescent devices are provided that contain the copolymeric material.

### BACKGROUND

Organic electroluminescent devices contain at least one organic electroluminescent material, a material capable of emitting light (e.g., visible wavelengths) when electrically activated. Organic electroluminescent devices such as organic light emitting diodes (OLEDs) are desirable for use in electronic media based on properties such as their thin profile, low weight, emission of various colors, and low driving voltage. OLEDs have potential use in various applications such as backlighting of graphics, pixelated displays, and large emissive graphics.

OLEDs contain an organic emitting element positioned between two electrodes (i.e., an anode and a cathode). The organic emitting element includes at least one light emitting layer that contains an electroluminescent material. Other layers such as charge transporting layers, charge blocking layers, and color conversion layers can be included in the organic emitting element. For example, OLEDs are often arranged in the following order: anode, hole transport layer, light emitting layer, electron transport layer, and cathode. Electrons are injected into the electron transport layer from the cathode and holes are injected into the hole transport layer from the anode. The charge carriers (i.e., holes and electrons) migrate to a light emitting layer where they combine to emit light. At least one of the electrodes is usually transparent and the light can be emitted through the transparent electrode.

The interface between the electrodes and the organic emitting element is known to influence the efficiency of organic electroluminescent devices. For example, manipulation of this interface has been recognized as a means of improving OLED properties such as efficiency of electron or hole injection into the light emitting layer and device lifetime.

### SUMMARY

A copolymeric material is provided that contains a phosphorous-containing group as well as a tertiary amino group. The phosphorus-containing group can be used to chemically bond the copolymeric material to a metal-containing surface such as an electrode of an organic electroluminescent device. The copolymeric material can function as a hole transport material within an organic electroluminescent device.

In one aspect, a copolymeric material is provided that is a reaction product of a monomer mixture that includes a first ethylenically unsaturated monomer and a second ethylenically unsaturated monomer. The first ethylenically unsaturated monomer has a phosphate group of formula —OP(═O)(OR²)₂ or a phosphonate group of formula —P(═O)(OR²)₂ where each R² is independently hydrogen, alkyl, aryl, or aralkyl. The second ethylenically unsaturated monomer has a tertiary amino group selected from an triarylamino group or a carbazolyl group.

In another aspect, an article is provided that includes a metal-containing surface and a copolymeric material chemically bonded to the metal-containing surface. The copolymeric material contains a phosphorous-containing group and a tertiary amino group. In some embodiments, the article is an organic electroluminescent device that includes a first electrode, a second electrode, and an organic emissive element positioned between the first and second electrodes. The organic emissive element contains the copolymeric material having the phosphorous-containing group and the tertiary amino group. The copolymeric material can be chemically bonded to the first electrode.

In yet another aspect, a method of making an organic electroluminescent device is described. The method includes providing a first electrode and a second electrode. The method further includes positioning an organic emissive element between the first and second electrode. The organic emissive element contains a copolymeric material having a phosphorous-containing group and a tertiary amino group. The copolymeric material can be chemically bonded to the first electrode.

The above summary of the present invention is not intended to describe each disclosed embodiment or every implementation of the present invention. The Figures, Detailed Description, and Examples that follow more particularly exemplify these embodiments.

### BRIEF DESCRIPTION OF THE DRAWINGS

The invention may be more completely understood in consideration of the following detailed description of various embodiments of the invention in connection with the accompanying drawings, in which:

FIGS. 1A to 1D are schematic side views of four embodiments of organic electroluminescent devices.

FIG. 2 is a schematic side view of an exemplary organic electroluminescent display construction.

FIG. 3 is a schematic side view of another exemplary organic electroluminescent display construction.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention.

### DETAILED DESCRIPTION

Copolymeric material is provided that can be included, for example, in an organic electroluminescent device. More specifically, the copolymeric material includes a phosphorous-containing group that is capable of forming a chemical bond with a metal-containing surface such as an electrode in an organic electroluminescent device. The copolymeric material also contains a tertiary amino group that can facilitate the transport of holes from the electrode (e.g., anode) to a light emitting layer of an organic electroluminescent device.

### DEFINITIONS

As used herein, the terms “a”, “an”, and “the” are used interchangeably with “at least one” to mean one or more of the elements being described.

As used herein, the term “alkyl” refers to a monovalent group that is derived from an alkane, which is a saturated hydrocarbon. The alkyl can be linear, branched, cyclic, or combinations thereof and typically contains 1 to 30 carbon atoms. In some embodiments, the alkyl group contains 1 to 20, 1 to 14, 1 to 10, 4 to 10, 4 to 8, 1 to 6, or 1 to 4 carbon atoms. Examples of alkyl groups include, but are not limited to, methyl, ethyl, n-propyl, isopropyl, n-butyl, tert-butyl, isobutyl, n-pentyl, n-hexyl, cyclohexyl, n-octyl, n-heptyl, and ethylhexyl.

As used herein, the term “alkylene” refers to a divalent group that is derived from an alkane. The alkylene can be straight-chained, branched, cyclic, or combinations thereof. The alkylene typically has 1 to 200 carbon atoms. In some embodiments, the alkylene contains 1 to 100, 1 to 80, 1 to 50, 1 to 30, 1 to 20, 1 to 10, 1 to 6, or 1 to 4 carbon atoms.

As used herein, the term “alkoxy” refers to a monovalent group of formula —OR where R is an alkyl group. Examples of alkoxy groups include methoxy, ethoxy, propoxy, butoxy, and the like.

As used herein, the term “aralkyl” refers to a monovalent group of formula —R—Ar where Ar is an aromatic carbocyclic group and R is an alkylene group.

As used herein, the term “aryl” refers to a monovalent aromatic carbocyclic group. The aryl can have one aromatic ring or can include up to 5 carbocyclic ring structures that are connected to or fused to the aromatic ring. The other ring structures can be aromatic, non-aromatic, or combinations thereof. Examples of aryl groups include, but are not limited to, phenyl, biphenyl, terphenyl, anthryl, naphthyl, acenaphthyl, anthraquinonyl, phenanthryl, anthracenyl, tetracenyl, pyrenyl, perylenyl, and fluorenyl.

As used herein, the term “arylene” refers to a divalent group derived from a carbocyclic aromatic compound having one to five rings that are connected, fused, or combinations thereof. In some embodiments, the arylene group has up to 5 rings, up to 4 rings, up to 3 rings, up to 2 rings, or one aromatic ring. For example, the arylene group can be phenylene.

As used herein, the term “carbazolyl” refers to a monovalent group derived from a carbazole.

As used herein, the term “carbonyloxy” refers to a divalent group of formula —(CO)O—.

As used herein, the term “diarylamino” refers to a group of formula —N(Ar^{b})₂ where each Ar^{b} is independently an aryl group.

As used herein, the term “ethylenically unsaturated” refers to a monovalent group having a carbon-carbon double bond of formula —CY═CH₂ where Y is hydrogen, alkyl, or aryl.

As used herein, the term “halo” refers to a halogen group (i.e., F, Cl, Br, or I).

As used herein, the term “haloalkyl” refers to an alkyl group having a halo substituent.

As used herein, the term “heteroalkylene” refers to a divalent alkylene having one or more carbon atoms replaced with a sulfur, oxygen, or NR^{a} where R^{a} is hydrogen or alkyl. The heteroalkylene can be linear, branched, cyclic, or combinations thereof and can include up to 400 carbon atoms and up to 30 heteroatoms. In some embodiments, the heteroalkylene includes up to 300 carbon atoms, up to 200 carbon atoms, up to 100 carbon atoms, up to 50 carbon atoms, up to 30 carbon atoms, up to 20 carbon atoms, or up to 10 carbon atoms.

As used herein, the term “hydroxy” refers to a group of formula —OH.

As used herein, the terms “polymer” or “polymeric” refer to a material that is a homopolymer or copolymer. Likewise, the terms “polymerize” or “polymerization” refer to the process of making a homopolymer or copolymer. As used herein, the term “homopolymer” refers to a polymeric material prepared using one monomer. As used herein, the term “copolymer” refers to a polymeric material that is prepared using two or more different monomers.

As used herein, the term “phosphate” refers to a group of formula —OP(═O)(OR²)₂ where each R² is independently hydrogen, alkyl, aryl, or aralkyl.

As used herein, the term “phosphonate” refers to a group of formula —P(═O)(OR²)₂ where each R² is independently hydrogen, alkyl, aryl, or aralkyl.

As used herein, the term “triarylamino” refers to group of formula —Ar^{a}—N(Ar^{b})₂ where Ar^{a} is an arylene group and each Ar^{b} is independently an aryl group.

Copolymeric Material

A copolymeric material is provided that is a reaction product of a monomer mixture that includes a first ethylenically unsaturated monomer and a second ethylenically unsaturated monomer. The first ethylenically unsaturated monomer has a phosphorous-containing group selected from a phosphate group of formula —OP(═O)(OR²)₂ or a phosphonate group of formula —P(═O)(OR²)₂ where each R² is independently hydrogen, alkyl, aryl, or aralkyl. The second ethylenically unsaturated monomer has a tertiary amino group selected from a triarylamino group or a carbazolyl group. Some copolymeric material includes more than one first ethylenically unsaturated monomer, more than one second ethylenically unsaturated monomer, or a combination thereof.

In some embodiments, the first ethylenically unsaturated monomer is of Formula I. 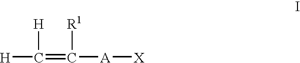
In Formula I, R¹ is hydrogen or alkyl. Suitable alkyl groups for R¹ often have up to 10, up to 8, up to 6, or up to 4 carbon atoms. In some monomers of Formula I, R¹ is hydrogen or methyl. The group X is a phosphorous-containing group selected from a phosphate group of formula —OP(═O)(OR²)₂ or a phosphonate group of formula —P(═O)(OR²)₂, wherein each R² is independently hydrogen, alkyl, aryl, or aralkyl. Suitable alkyl groups for R² often have up to 10, up to 8, up to 6, or up to 4 carbon atoms. Suitable aryl groups for R² typically have up to 18, up to 12, or up to 6 carbon atoms. Suitable aralkyl groups for R² typically have up to 20, up to 16, up to 12, or up to 8 carbon atoms.

The group A in Formula I is a divalent linking group of formula -Q- or of formula —C(═O)OQ-. That is, the ethylenically unsaturated monomers of Formula I are according to Formula II or Formula III: 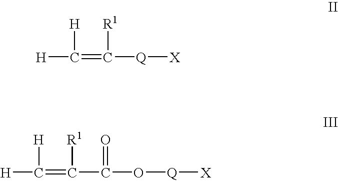
where the divalent linking group Q is a single bond, alkylene, heteroalkylene, arylene, or a combination thereof (e.g., an alkylene in combination with an arylene or an alkylene in combination with a heteroalkylene). The group Q can be unsubstituted or substituted with a hydroxy, alkoxy, alkyl, halo, haloalkyl, or combination thereof (i.e., multiple substituents).

Monomers according to Formula II can be vinyl monomers such as those where Q is a single bond or an alkylene as shown in the following formula. 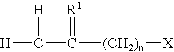
In this formula, n can be an integer of 0 to 20. The alkylene group can be unsubstituted or substituted with a hydroxy, alkoxy, alkyl, halo, haloalkyl, or combination thereof. Some exemplary monomers have n equal to 0 as shown in the following formula 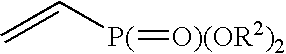
where each R² is independently hydrogen, alkyl, aryl, or aralkyl. More specific examples of this formula include, but are not limited to, vinylphosphonic acid (i.e., each R² is hydrogen) and diethyl vinylphosphonate (i.e., each R² is ethyl).

Other monomers according to Formula II include those where Q is a combination of an arylene and an alkylene such as in the following formula 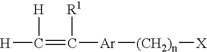
where Ar is an arylene and n is an integer of 0 to 20. X and R′ are the same as previously described for Formula II. Suitable arylene groups often have up to 18, up to 14, or up to 10 carbon atoms. In some monomers, the arylene is phenylene. The arylene or alkylene group can be unsubstituted or substituted with a hydroxy, alkoxy, alkyl, halo, haloalkyl, or combination thereof. One exemplary formula includes, but is not limited to, 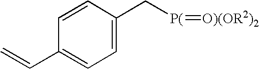
where each R² is independently hydrogen, alkyl, aryl, or aralkyl.

Monomers according to Formula III can be (meth)acrylates. As used herein, the term “(meth)acrylates” includes both acrylates (i.e., R¹ is hydrogen) and methacrylates (i.e., R¹ is methyl). Some of the (meth)acrylates have a Q group that is an alkylene, heteroalkylene, or a combination thereof as in the following formulas 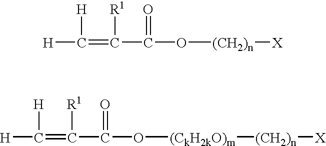
where n is an integer of 0 to 20, m is an integer of 1 to 50, and k is an integer of 1 to 5. The alkylene and heteroalkylene groups can be unsubstituted or substituted with a hydroxy, alkoxy, alkyl, halo, haloalkyl, or combination thereof. Exemplary compounds include, but are not limited to, 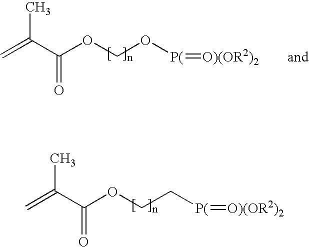
where each R² is independently hydrogen, alkyl, aryl, or aralkyl.

The Q group can also be a branched alkylene. Such a monomer can be of the following formula: 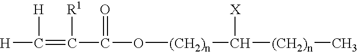
where each n is independently an integer of 0 to 20. The branched alkylene can be unsubstituted to substituted with a hydroxy, alkoxy, alkyl, halo, haloalkyl, or combination thereof. Exemplary compounds include 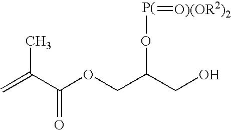
where each R² is independently hydrogen, alkyl, aryl, or aralkyl.

Some monomers according to Formula III contain an arylene group or an arylene group in combination with an alkylene group. Exemplary compounds include those of the following formula 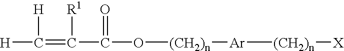
where Ar is an arylene and each n is independently an integer of 0 to 20. The alkylene or the arylene can be unsubstituted or substituted with a hydroxy, alkoxy, alkyl, halo, haloalkyl, or combination thereof. Suitable arylene groups often have up to 18, up to 14, or up to 10 carbon atoms. In some monomers, the arylene is phenylene. Such monomers include, for example, those of the following formula 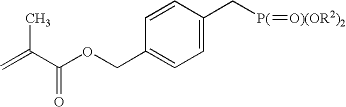
where each R² is independently hydrogen, alkyl, aryl, or aralkyl.

The monomer mixture typically contains up to 20 mole percent of the first ethylenically unsaturated monomer based on the total moles of monomer. Some monomer mixtures contain up to 15 mole percent, up to 12 mole percent, up to 10 mole percent, up to 8 mole percent, up to 6 mole percent, up to 4 mole percent, or up to 2 mole percent of the first ethylenically unsaturated monomer based on the total moles of monomer. The monomer mixture typically contains at least 0.1 mole percent, at least 0.2 mole percent, at least 0.3 mole percent, at least 0.5 mole percent, at least 1 mole percent, at least 1.5 mole percent, or at least 2 mole percent of the first ethylenically unsaturated monomer based on the total moles of monomer.

The second monomer in the monomer mixture used to prepare the copolymeric material is an ethylenically unsaturated monomer that has a tertiary amino group selected from a carbozolyl group or a triarylamino group. Monomers having a carbozolyl group include, for example, 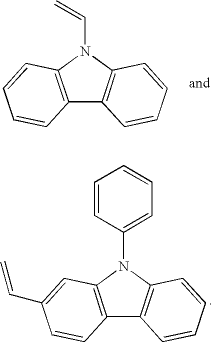
That is, the ethylenically unsaturated group can be bonded to any aromatic ring or to the nitrogen atom. An aryl group can be unsubstituted or substituted with a diarylamino, triarylamino, alkyl, alkoxy, halo, haloalkyl, hydroxy, or combination thereof.

In some copolymeric material, the second ethylenically unsaturated monomer is of Formula IV where the tertiary amino group is a triarylamino group. 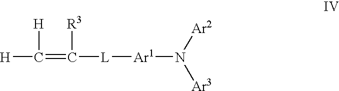
In Formula IV, R³ is hydrogen or alkyl. Suitable alkyl groups for R³ often have up to 10, up to 8, up to 6, or up to 4 carbon atoms. In some monomers of Formula IV, R³ is hydrogen or methyl. The group L is a divalent linking group selected from single bond, carbonyloxy, alkylene, heteroalkylene, arylene, or a combination thereof (e.g., an arylene combined with an alkylene or a carbonyloxy combined with an alkylene).

Ar¹ in Formula IV is an arylene that is unsubstituted or substituted with a diarylamino, triarylamino, alkyl, alkoxy, halo, haloalkyl, hydroxy, or combination thereof. Ar² and Ar³ are each independently an aryl that is unsubstituted or substituted with a diarylamino, triarylamino, alkyl, alkoxy, halo, haloalkyl, hydroxy, or combination thereof. Alternatively, Ar² and Ar³ plus a nitrogen atom to which both Ar² and Ar³ are attached can combine to form a fused aromatic group that is unsubstituted or substituted with a diarylamino, triarylamino, alkyl, alkoxy, halo, haloalkyl, hydroxy, or combination thereof. In some exemplary monomers, the groups Ar¹, Ar², and Ar³ are each independently derived from benzene, biphenyl, naphthalene, anthracene, tetracene, fluorene, phenanthrene, pyrene, or the like that is unsubstituted or substituted with a diarylamino, triarylamino, alkyl, alkoxy, halo, haloalkyl, hydroxy, or combination thereof.

In some monomers of Formula II, the group L can be a single bond according to the following formula 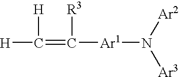
where R³, Ar¹, Ar², and Ar³ are the same as defined for Formula II. Such monomers include, for example,

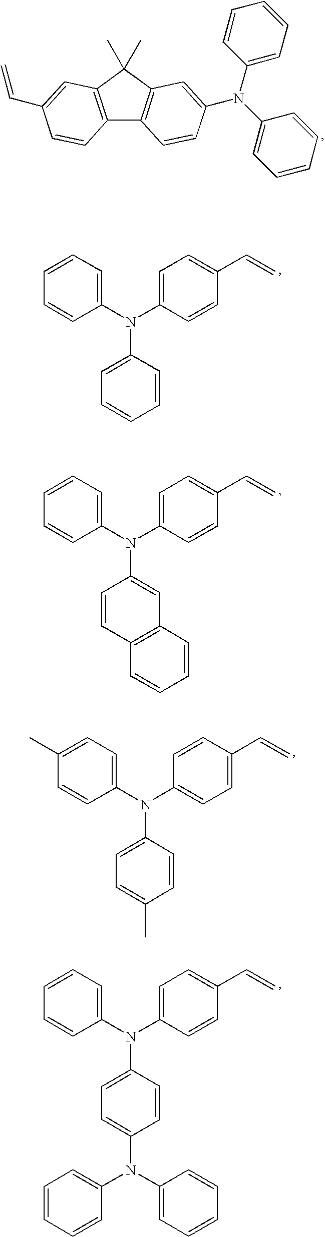

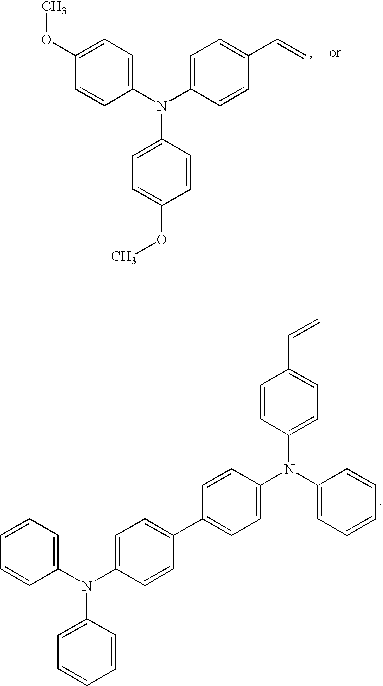

In other exemplary monomers where L in Formula IV is a single bond, the groups Ar² and Ar³ plus the nitrogen to which they are attached combine to form a carbozolyl group. Exemplary monomers include, but are not limited to, 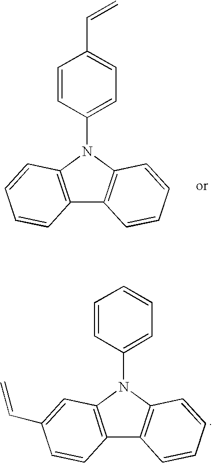
that can be unsubstituted or substituted with a diarylamino, triarylamino, alkyl, alkoxy, halo, haloalkyl, hydroxy, or combination thereof.

In still other monomers according to Formula IV, the group L has an arylene group bonded directly to the ethylenically unsaturated group as shown in the following formula 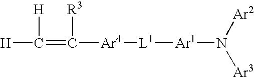
where Ar⁴ is an arylene and L¹ is selected from a single bond, alkylene, or heteroalkylene. The groups R³, Ar¹, Ar², and Ar³ are the same as previously defined for Formula IV. Suitable Ar⁴ groups are derived, for example, from benzene, biphenyl, naphthalene, anthracene, fluorene, phenanthrene, pyrene, or the like. In some monomers, Ar⁴ is phenylene. The group —Ar⁴-L¹-can be unsubstituted or substituted with a diarylamino, triarylamino, alkyl, alkoxy, halo, haloalkyl, hydroxy, or combination thereof. One specific exemplary monomer includes, but is not limited to,

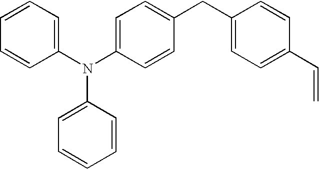

Other monomers of Formula IV can have a carbonyloxy group bonded directly to the ethylenically unsaturated group via the carbonyl group. That is, the monomers can be of formula 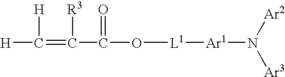
where R³, Ar¹, Ar², and Ar³ are the same as described for Formula IV. The group L¹ can be a single bond, an alkylene, a heteroalkylene, or a combination thereof. In some exemplary monomers, the groups Ar¹, Ar², and Ar³ are independently derived from benzene, biphenyl, naphthalene, anthracene, fluorene, phenanthrene, pyrene, or the like that is unsubstituted or substituted with a diarylamino, triarylamino, alkyl, alkoxy, halo, haloalkyl, hydroxy, or combination thereof.

The monomers having a carbonyloxy group bonded to the ethylenically unsaturated group can be acrylates where R³ is hydrogen or methacrylates where R³ is methyl. Suitable (meth)acrylates include, but are not limited to,

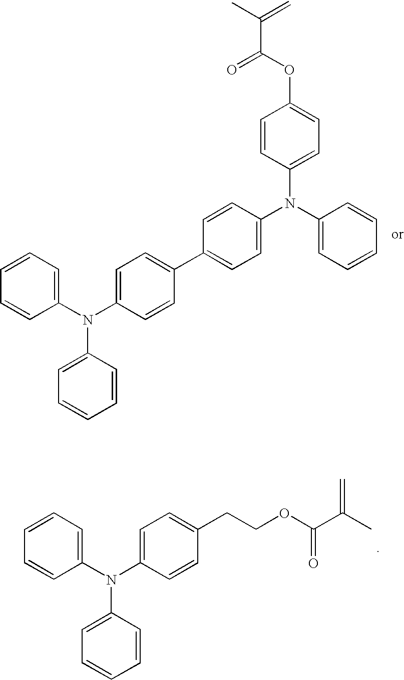

The monomer mixture often contains at least 5 mole percent of the second ethylenically unsaturated monomer based on the total moles of monomers. Some monomer mixtures contain at least 10 mole percent, at least 20 mole percent, at least 30 mole percent, at least 40 mole percent, or at least 50 mole percent based of the second ethylenically unsaturated monomer based on the total moles of monomers.

The monomer mixture can include a third ethylenically unsaturated monomer in addition to the first and second ethylenically unsaturated monomers. The third monomer can be unsubstituted or substituted, for example, with a hydroxy, alkoxy, alkyl, halo, haloalkyl, or combination thereof. Suitable third ethylenically unsaturated monomers include, for example, vinyl aromatic monomers such as styrene, α-methylstyrene, 2-vinyl pyridine, 4-vinyl pyridine, and the like; α,β-unsaturated carboxylic acids and their derivatives such as acrylic acid, methacrylic acid, itaconic acid, maleic acid, fumaric acid, crotonic acid, methyl methacrylate, butyl methacrylate, 2-ethylhexyl methacrylate, ethyl acrylate, butyl acrylate, iso-octyl acrylate, octadecyl acrylate, cyclohexyl acrylate, tetrahydrofurfuryl methacrylate, phenyl acrylate, phenethyl acrylate, benzyl methacrylate, β-cyanoethyl acrylate, maleic anhydride, diethyl itaconate, acrylamide, methacrylonitrile, N-butylacrylamide, and the like; vinyl esters of carboxylic acids such as vinyl acetate, vinyl 2-ethylhexanoate, and the like; vinyl halides such as vinyl chloride, vinylidene chloride, and the like; N-vinyl compounds such as N-vinylpyrrolidone and N-vinylcaprolactone (i.e., 9-vinylcaprolactone); vinyl ketones such as methyl vinyl ketone and the like; and combinations thereof.

The copolymeric material can be prepared by free radical polymerization. A thermal free radical polymerization reaction can be commenced, for example, by forming an initiating free radical from initiators such as, for example, azo compounds, peroxide compounds, persulfate compounds, or redox systems. Suitable azo compounds include, but are not limited to, 2,2′-azobis(isobutyronitrile) (AIBN); azobis(valeronitrile); azobis(2-cyanovaleric acid); 2,2′-azobis(2-methylpropionamidine)dihydrochloride; 2,2′-azobis(4-methoxy-2,4-dimethlvaleronitrile); 2,2′-azobis(amidinopropane) dihydrochloride; 2,2′-azobis-2-methylbutyronitrile; 1,1′-azobis(1-cyclohexadecanecarbonitrile); and 2,2′-azobis(methyl isobutyrate). Suitable peroxides include, but are not limited to, hydroperoxides such as cumene hydroperoxide, tert-butyl hydroperoxide, and tert-amyl hydroperoxide; dialkyl peroxides such as di-tert-butyl peroxide and dicumyl peroxide; peroxyesters such as tert-butylperbenzoate and di-tert-butylperoxy phthalate; and diacylperoxides such as benzoyl peroxide and lauroyl peroxide. Suitable persulfates include, but are not limited to, ammonium persulfate, sodium persulfate, and potassium persulfate. Suitable redox (oxidation-reduction) initiators include, but are not limited to, systems based on organic peroxides and tertiary amines, for example, benzoyl peroxide plus dimethylaniline; and systems based on organic hydroperoxides and transition metals, for example, cumene hydroperoxide plus cobalt naphthenate.

In addition to thermal free radical polymerization, the copolymeric material can also be prepared by photochemical free radical polymerization. Typically, the monomers are irradiated with ultraviolet (UV) light in the presence of a photopolymerization initiator (i.e., photoinitiators). Suitable photoinitiators include those available under the trade designations IRGACURE and DAROCUR from Ciba Speciality Chemical Corp., Tarrytown, N.Y. such as 1-hydroxy cyclohexyl phenyl ketone (IRGACURE 184), 2,2-dimethoxy-1,2-diphenylethan-1-one (IRGACURE 651), bis(2,4,6-trimethylbenzoyl)phenylphosphine oxide (IRGACURE 819), 1-[4-(2-hydroxyethoxy)phenyl]-2-hydroxy-2-methyl-1-propane-1-one (IRGACURE 2959), 2-benzyl-2-dimethylamino-1-(4-morpholinophenyl)butanone (IRGACURE 369), 2-methyl-1-[4-(methylthio)phenyl]-2-morpholinopropan-1-one (IRGACURE 907), and 2-hydroxy-2-methyl-1-phenyl propan-1-one (DAROCUR 1173). For example, the copolymeric material can be prepared using photoinitiators selected from IRGACURE 819, IRGACURE 2959, or a combination thereof.

The resulting copolymeric material usually has a weight average molecular weight (M_{w}) greater than 1000 g/mole, greater than 2000 g/mole, greater than 3000 g/mole or greater than 5000 g/mole.

Organic Electronic Devices

In another aspect, an article is provided that includes a metal-containing surface and a copolymeric material chemically bonded to the metal-containing surface (i.e., the article is the reaction product of a copolymeric material and a metal-containing surface). As used herein, the term “metal-containing” refers to a material that contains a metallic species such as an elemental metal, an alloy, an intermetallic compound, a metal oxide, a metal nitride, metal sulfides, or combinations thereof. In many embodiments, the metal-containing surface contains one or more metal oxides. For example, the metal-containing surface can be an electrode such as an anode that includes metal oxides.

The copolymeric material used in the article contains a phosphorous-containing group as well as a tertiary amino group. The copolymeric material is a reaction product of a monomer mixture that includes a first ethylenically unsaturated monomer and a second ethylenically unsaturated monomer. The first ethylenically unsaturated monomer has a phosphate group of formula —OP(═O)(OR²)₂ or phosphonate group of formula —P(═O)(OR²)₂ where each R² is independently hydrogen, alkyl, aryl, or aralkyl. The second ethylenically unsaturated monomer has a tertiary amino group selected from a triarylamino group or a carbazolyl group.

In some embodiments, the article is an organic electroluminescent device (OEL) that includes a first electrode, a second electrode, and an organic emissive element positioned between the first and second electrodes. The organic emissive element contains the copolymeric material with the phosphorous-containing group and the tertiary amino group. The copolymeric material can be chemically bonded to the surface of the first electrode through the phosphate or phosphonate group.

The organic emissive element usually includes at least one light emitting layer that contains one or more organic electroluminescent materials. Other layers can be present in the organic emissive element such as hole transport layers, electron transport layers, hole injection layers, electron injection layers, hole blocking layers, electron blocking layers, buffer layers, phosphor layers, and the like. In addition, photoluminescent materials can be present in the light emitting layer or other layers in OEL devices, for example, to convert the color of light emitted by the electroluminescent material to another color. These and other such layers and materials can be used to alter or tune the electronic properties and behavior of the layered OEL device.

The copolymeric material with a phosphorous-containing group and a tertiary amino group is typically included in at least the layer of the organic emissive element that contacts the first electrode (e.g., anode). The phosphate or phosphonate group of the copolymeric material can form a chemical bond with a metal-containing surface such as the surface of the first electrode. Within any layer of the organic emissive element, the copolymeric material can be present alone or in combination with other materials.

The copolymeric material can modify the work function of the first electrode (e.g., anode) and can provide a smooth surface for the deposition of other layers of the organic emissive element. The copolymeric material can function as a hole transporting material. Additionally, the copolymeric material can often reduce the formation of short circuits in the organic electroluminescent device. These short circuits can cause the formation of dark spots in a display and can decrease the lifetime of the device. In some instances, these short circuits can cause catastrophic device failure.

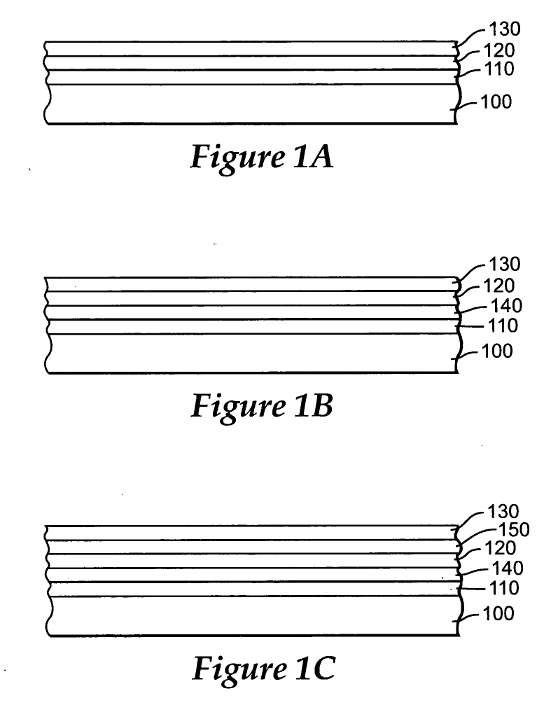

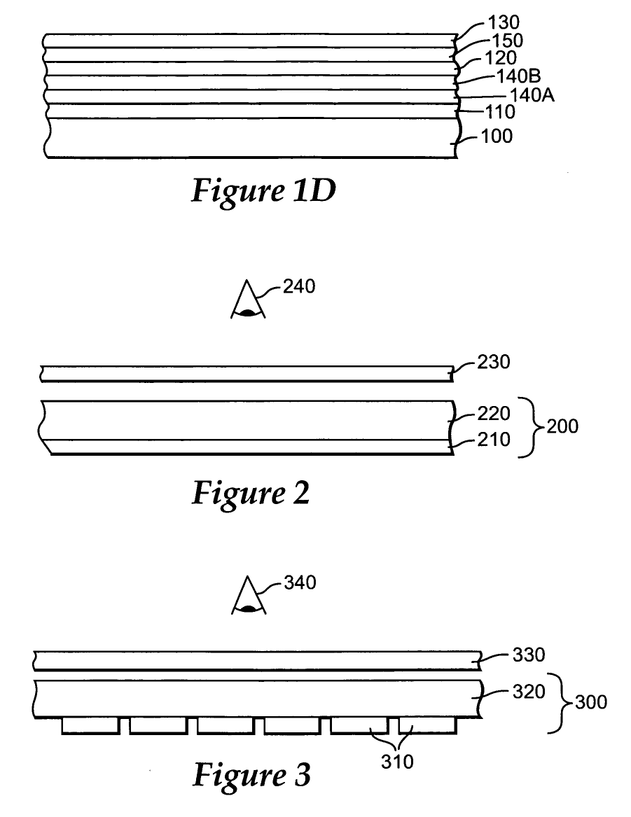

FIGS. 1A to 1D illustrate various configurations of OEL devices (for example, an organic light emitting diode). Each of these configurations includes a substrate 100, an anode 110, a cathode 130, and a light emitting layer 120. The configurations of FIG. 1B includes a hole transport layer 140 and the configuration of FIG. 1C includes both a hole transport layer 140 and an electron transport layer 150. A hole transport layer can conduct holes from the anode and an electron transport layer can conduct electrons from the cathode. Each of these layers depicted in FIGS. 1A to 1C can include multiple layers of material. For example, the hole transport layer can include a first hole transport layer 140A and a second hole transport layer 140B as illustrated in FIG. 1D. The copolymeric material having a phosphorous-containing group and a tertiary amino group is often in the hole transport layer 140, in the light emitting layer 120, or in a combination of both the hole transport layer 140 and the light emitting layer 120. When the organic emissive element contains multiple hole transport layers, the copolymeric material is usually present at least in the hole transport layer that contacts the anode.

The anode 110 and cathode 130 are typically formed using conducting materials such as metals, alloys, metallic compounds, conductive metal oxides, conductive ceramics, conductive dispersions, and conductive polymers, including, for example, gold, silver, nickel, chromium, barium, platinum, palladium, aluminum, calcium, titanium, indium tin oxide (ITO), fluorine tin oxide (FTO), antimony tin oxide (ATO), indium zinc oxide (IZO), poly(3,4-ethylenedioxythiophene)/poly(styrene sulfonate), polyaniline, other conducting polymers, alloys thereof, or combinations thereof. The anode 110 and the cathode 130 can be single layers of conducting materials or can include multiple layers of conducting materials. For example, an anode or a cathode may include a layer of aluminum and a layer of gold, a layer of calcium and a layer of aluminum, a layer of aluminum and a layer of lithium fluoride, or a metal layer and a conductive organic layer.

A typical anode for an organic electroluminescent device is indium-tin-oxide (ITO) sputtered onto a transparent substrate such as plastic or glass. Suitable substrates include, for example, glass, transparent plastics such as polyolefins, polyethersulfones, polycarbonates, polyesters, polyarylates, and polymeric multilayer films, ITO coated barrier films such as the Plastic Film Conductor available from 3M (St. Paul, Minn.), surface-treated films, and selected polyimides.

The anode material coating the substrate is electrically conductive and may be optically transparent, semi-transparent, or opaque. In addition to ITO, suitable anode materials include indium oxide, fluorine tin oxide (FTO), zinc oxide, indium zinc oxide (IZO), vanadium oxide, zinc-tin oxide, gold, platinum, palladium silver, other high work function metals, and combinations thereof. Many suitable anodes have a surface that contains one or more metal oxides.

Typical cathodes include low work function metals such as aluminum, barium, calcium, samarium, magnesium, silver, magnesium/silver alloys, lithium, lithium fluoride, ytterbium, and of calcium/magnesium alloys. The cathode can be a single layer or multiple layers of these materials. For example, the cathode can include a layer of lithium fluoride, a layer of aluminum, and a layer of silver.

The hole transport layer 140 facilitates the injection of holes from the anode into the device and their migration towards the recombination zone within the light emitting layer. The hole transport layer 140 can further act as a barrier for the passage of electrons to the anode 100. The copolymeric material having a phosphorous-containing group and a tertiary amino group is often in a hole transport layer. The copolymeric material can be used as the sole hole transport material or can be combined with a second hole transport material in any hole transport layer.

In some examples, the hole transport layer has at least two layers as shown in FIG. 1D. The first hole transport layer 140A is in contact with the anode 110 and can include the copolymeric material with a phosphorous-containing group and a tertiary amino group. The second hole transport layer 140B can include, for example, a second hole transport material selected from a diamine derivative such as N,N′-bis(3-methylphenyl)-N,N′-bis(phenyl)benzidine (TPD), N,N′-bis(2-naphthyl)-N,N′-bis(phenyl)benzidine (beta-NPB), N,N′-bis(1-naphthyl)-N,N′-bis(phenyl)benzidine (NPB), or the like; or a triarylamine derivative such as, 4,4′,4″-tris(N,N-diphenylamino)triphenylamine (TDATA), 4,4′,4″-tris(N-3-methylphenyl-N-phenylamino)triphenylamine (MTDATA), 4,4′,4″-tri(N-phenoxazinyl) triphenylamine (TPOTA), 1,3,5-tris(4-diphenylaminophenyl)benzene (TDAPB), or the like.

The organic electroluminescent device contains one or more light emitting layers 120. The copolymeric material with a phosphorous-containing group and a tertiary amino group can be present in one or more of the light emitting layers. Other materials that are capable of emitting light can be present in the same layer or in a different light emitting layer than the copolymeric material. Some light emitting layers have a small molecule (SM) emitter, a small molecule emitter doped polymer, a light emitting polymer (LEP), a small molecule emitter doped light emitting polymer, a blend of light emitting polymers, or a combination thereof. The emitted light from the organic emissive element can be in any portion of the visible spectrum depending on the composition of the light emitting layer or layers.

In some embodiments, the organic emissive element has a light emitting layer that contains a light emitting polymer. LEP materials are typically conjugated polymeric or oligomeric molecules that preferably have sufficient film-forming properties for solution processing. As used herein, “conjugated polymers or oligomeric molecules” refer to polymers or oligomers having a delocalized π-electron system along the polymer backbone. Such polymers or oligomers are semiconducting and can support positive and negative charge carriers along the polymeric or oligomeric chain.

Exemplary LEP materials include poly(phenylenevinylenes), poly(para-phenylenes), polyfluorenes, other LEP materials now known or later developed, and co-polymers or blends thereof. Suitable LEPs can also be doped with a small molecule emitter, dispersed with fluorescent dyes or photoluminescent materials, blended with active or non-active materials, dispersed with active or non-active materials, and the like. Examples of suitable LEP materials are further described in Kraft, et al., Angew. Chem. Int. Ed., 37, 402-428 (1998); U.S. Pat. Nos. 5,621,131; 5,708,130; 5,728,801; 5,840,217; 5,869,350; 5,900,327; 5,929,194; 6,132,641; and 6,169,163; and PCT Patent Application Publication No. 99/40655.

LEP materials can be formed into a light emitting structure, for example, by casting a solvent solution of the LEP material on a substrate and evaporating the solvent to produce a polymeric film. Alternatively, LEP material can be formed in situ on a substrate by reaction of precursor species. Suitable methods of forming LEP layers are described in U.S. Pat. No. 5,408,109, incorporated herein by reference. Other methods of forming a light emitting structure from LEP materials include, but are not limited to, laser thermal patterning, inkjet printing, screen printing, thermal head printing, photolithographic patterning, and extrusion coating.

In some embodiments, the organic electroluminescent material can include one or more small molecule emitters. SM electroluminescent materials include charge transporting, charge blocking, and semiconducting organic or organometallic compounds. Typically, SM materials can be vacuum deposited or coated from solution to form thin layers in a device. In practice, multiple layers of SM materials are typically used to produce efficient organic electroluminescent devices since a given material generally does not have both the desired charge transport and electroluminescent properties.

Exemplary SM materials include N,N′-bis(3-methylphenyl)-N,N′-diphenylbenzidine (TPD) and metal chelate compounds such as tris(8-hydroxyquinoline) aluminum (Alq3) and biphenylato bis(8-hydroxyquinolato)aluminum (BAlq). Other SM materials are disclosed in, for example, C. H. Chen, et al., Macromol. Symp. 125, 1 (1997); Japanese Laid Open Patent Application 2000-195673; U.S. Pat. Nos. 6,030,715; 6,150,043; and 6,242,115; and PCT Patent Applications Publication Nos. WO 00/18851 (divalent lanthanide metal complexes), WO 00/70655 (cyclometallated iridium compounds and others), and WO 98/55561. Some of these small molecules can be fluorescent and/or phosphorescent.

The light emitting layer can contain a host material in combination with a dopant The excited state of the host material is typically at a higher energy level than the excited state of the dopant so that energy can be transferred from the host material to the dopant. The excited host material typically emits light of a shorter wavelength than the excited dopant. For example, host material that emits blue light can transfer energy to a dopant that emits green or red light and a host material that emits green light can transfer energy to a dopant that emits red light but not to a dopant that emits blue light. Exemplary host material and dopant combinations include, but are not limited to, the Alq3 doped with coumarin dyes and BAlq doped with rubrene.

The electron transport layer 150 facilitates the injection of electrons from the cathode into the device and migration of electrons towards the recombination zone within the light emitting layer 120. The electron transport layer 150 can further act as a barrier for the passage of holes to the cathode 130. In some examples, the electron transport layer 150 can be formed using the organometallic compound such as tris(8-hydroxyquinolato) aluminum (Alq3) and biphenylato bis(8-hydroxyquinolato)aluminum (BAlq). Other examples of electron transport materials useful in electron transport layer 150 include 1,3-bis[5-(4-(1,1-dimethylethyl)phenyl)-1,3,4-oxadiazol-2-yl]benzene; 2-(biphenyl-4-yl)-5-(4-(1,1-dimethylethyl)phenyl)-1,3,4-oxadiazole; 9,10-di(2-naphthyl)anthracene (ADN); 2-(4-biphenyl)-5-(4-t-butylphenyl)-1,3,4-oxadiazole; or 3-(4-biphenylyl)-4-phenyl-5-(4-tert-butylphenyl)-1,2,4-triazole (TAZ).

Other layers such as additional hole injection layers containing, for example, porphyrinic compounds like copper phthalocyanine (CuPc) or zinc phthalocyanine; electron injection layers containing, for example, alkaline metal oxides or alkaline metal salts; hole blocking layers containing, for example, molecular oxadiazole or triazole derivatives such as 2-(4-biphenyl)-5-(4-t-butylphenyl)-1,3,4-oxadiazole (PBD), 2,9-dimethyl-4,7-diphenyl-1,10-phenanthraline (BCP), biphenylato bis(8-hydroxyquinolato)aluminum (BAlq), or 3-(4-biphenylyl)-4-phenyl-5-(4-tert-butylphenyl)-1,2,4-triazole (TAZ); electron blocking layers containing, for example, N,N′-bis(1-naphthyl)-N,N′-bis(phenyl) benzidine (NPB), or 4,4′,4″-tris(N-(3-methylphenyl)-N-phenylamino)triphenylamine (MTDATA); or the like can also be present in organic emissive element. In addition, photoluminescent materials can be present in these layers, for example, to convert the color of light emitted by the electroluminescent material to another color. These and other such layers and materials can be used to alter or tune the electronic properties and behavior of the layered OEL device, for example, to achieve one or more features such as a desired current/voltage response, a desired device efficiency, a desired color, a desired brightness, a desired device lifetime, or a desired combination of these features.

One or more organic electroluminescent devices can be used to form an organic electroluminescent display. FIG. 2 illustrates an exemplary OEL display 200 that includes an organic electroluminescent device layer 210 and a substrate 220. Any other suitable display component can also be included with the OEL display 200. Optionally, additional optical elements or other devices suitable for use with electronic displays, devices, or lamps can be provided between display 200 and viewer position 240 as indicated by optional element 230.

In some embodiments like the one shown, OEL device layer 210 includes one or more OEL devices that emit light through the substrate toward a viewer position 240. The viewer position 240 is used generically to indicate an intended destination for the emitted light whether it be an actual human observer, a screen, an optical component, an electronic device, or the like. In other embodiments (not shown), device layer 210 is positioned between substrate 220 and the viewer position 240. The device configuration shown in FIG. 2 (termed “bottom emitting”) may be used when substrate 220 is transmissive to light emitted by device layer 210 and when a transparent conductive electrode is disposed in the device between the light emitting layer of the device and the substrate. The inverted configuration (termed “top emitting”) may be used when substrate 220 does or does not transmit the light emitted by the device layer and the electrode disposed between the substrate and the light emitting layer of the device does not transmit the light emitted by the device. Some devices can have two transparent conductive electrodes and a substrate that is transmissive. Such devices can be transparent and can be both top and bottom emitting.

Device layer 210 can include one or more OEL devices arranged in any suitable manner. For example, in lamp applications (e.g., backlights for liquid crystal display (LCD) modules), device layer 210 might constitute a single OEL device that spans an entire intended backlight area. Alternatively, in other lamp applications, device layer 210 might constitute a plurality of closely spaced devices that can be contemporaneously activated. For example, relatively small and closely spaced red, green, and blue light emitters can be patterned between common electrodes so that device layer 210 appears to emit white light when the emitters are activated. Other arrangements for backlight applications are also contemplated.

In direct view or other display applications, it may be desirable for device layer 210 to include a plurality of independently addressable OEL devices or elements that emit the same or different colors. Each device might represent a separate pixel or a separate sub-pixel of a pixelated display (e.g., high resolution or low resolution displays), a separate segment or sub-segment of a segmented display (e.g., low information content display), or a separate icon, portion of an icon, or lamp for an icon (e.g., indicator applications).

Referring back to FIG. 2, OEL device layer 210 is disposed on substrate 220. Substrate 220 can be any substrate suitable for OEL device and display applications. For example, substrate 220 can include glass, paper, woven or non-woven materials, polymeric, or other suitable material(s) that are substantially transparent to visible light. Suitable substrates can be clear, transparent or translucent, rigid or flexible, filled or unfilled. Substrate 220 can also be opaque to visible light, for example stainless steel, crystalline silicon, amorphous silicon, poly-silicon, or the like. Because some materials in OEL devices can be particularly susceptible to damage due to exposure to oxygen or moisture, substrate 220 preferably provides an adequate environmental barrier, or is supplied with one or more layers, coatings, or laminates that provide an adequate environmental barrier.

Substrate 220 can also include any number of devices or components suitable in OEL devices and displays such as transistor arrays and other electronic devices; color filters, polarizers, wave plates, diffusers, and other optical devices; insulators, barrier ribs, black matrix, mask work and other such components; and the like. Generally, one or more electrodes will be coated, deposited, patterned, or otherwise disposed on substrate 220 before forming the remaining layer or layers of the OEL device or devices of the device layer 210. When a light transmissive substrate 220 is used and the OEL device or devices are bottom emitting, the electrode or electrodes that are disposed between the substrate 220 and the emissive material(s) are preferably substantially transparent to light, for example transparent conductive electrodes such as indium tin oxide (ITO) or any of a number of other transparent conductive oxides.

Element 230 can be any element or combination of elements suitable for use with OEL display or device 200. For example, element 230 can be a LCD module when device 200 is a backlight. One or more polarizers or other elements can be provided between the LCD module and the backlight device 200, for instance an absorbing or reflective clean-up polarizer. Alternatively, when device 200 is itself an information display, element 230 can include one or more of polarizers, wave plates, touch panels, antireflective coatings, anti-smudge coatings, projection screens, brightness enhancement films, or other optical components, coatings, user interface devices, or the like.

In one embodiment, OEL displays can be made that emit light and that have adjacent devices or elements that can emit light having different color. For example, FIG. 3 shows an exemplary OEL display 300 that includes a plurality of OEL elements 310 adjacent to each other and disposed on a substrate 320. Two or more adjacent elements 310 can be made to emit different colors of light, for example red, green, and blue. Optionally, additional optical elements 330 suitable for use with electronic displays, devices, or lamps can be provided between the display 300 and viewer position 340.

The separation shown between elements 310 is for illustrative purposes only. Adjacent devices may be separated, in contact, overlapping, etc., or different combinations of these in more than one direction on the display substrate. For example, a pattern of parallel striped transparent conductive anodes can be formed on the substrate followed by a striped pattern of a hole transport material and a striped repeating pattern of red, green, and blue light emitting layers, followed by a striped pattern of cathodes, the cathode stripes oriented perpendicular to the anode stripes. Such a construction may be suitable for forming passive matrix displays. In other embodiments, transparent conductive anode pads can be provided in a two-dimensional pattern on the substrate and associated with addressing electronics such as one or more transistors, capacitors, etc., such as are suitable for making active matrix displays. Other layers, including the light emitting layer(s) can then be coated or deposited as a single layer or can be patterned (e.g., parallel stripes, two-dimensional pattern commensurate with the anodes, etc.) over the anodes or electronic devices. Any other suitable construction is also contemplated by the present invention.

In one embodiment, display 300 in FIG. 3 can be a multiple color display. In exemplary embodiments, each of the elements 310 emits light. There are many displays and devices constructions covered by the general construction illustrated in FIG. 2. Some of those constructions are discussed as follows.

Constructions of OEL backlights can include bare or circuitized substrates, anodes, cathodes, hole transport layers, electron transport layers, hole injection layers, electron injection layers, emissive layers, color changing layers, and other layers and materials suitable in OEL devices. Constructions can also include polarizers, diffusers, light guides, lenses, light control films, brightness enhancement films, and the like. Applications include white or single color large area single pixel lamps as well as white or single color large area single electrode pair lamps with a large number of closely spaced emissive layers.

Constructions of low resolution OEL displays can include bare or circuitized substrates, anodes, cathodes, hole transport layers, electron transport layers, hole injection layers, electron injection layers, emissive layers, color changing layers, and other layers and materials suitable in OEL devices. Constructions can also include polarizers, diffusers, light guides, lenses, light control films, brightness enhancement films, and the like. Applications include graphic indicator lamps (e.g., icons); segmented alphanumeric displays (e.g., appliance time indicators); small monochrome passive or active matrix displays; small monochrome passive or active matrix displays plus graphic indicator lamps as part of an integrated display (e.g., cell phone displays); large area pixel display tiles (e.g., a plurality of modules, or tiles, each having a relatively small number of pixels), such as may be suitable for outdoor display used; and security display applications.

Constructions of medium to high resolution OEL displays can include bare or circuitized substrates, anodes, cathodes, hole transport layers, electron transport layers, hole injection layers, electron injection layers, emissive layers, color changing layers, and other layers and materials suitable in OEL devices. Constructions can also include polarizers, diffusers, light guides, lenses, light control films, brightness enhancement films, and the like. Applications include active or passive matrix multicolor or full color displays; active or passive matrix multicolor or full color displays plus segmented or graphic indicator lamps and security display applications.

In yet another aspect, a method of preparing an article is provided. The method includes providing a metal-containing surface; and applying a coating composition to the metal-containing surface. The coating composition contains a copolymeric material that has a phosphorous-containing group and a tertiary amino group.

The copolymeric material can be formed as a film that is chemically bonded to a metal-containing surface such as the anode of an organic electroluminescent device. Any excess copolymeric material that is not chemically bonded to the metal-containing surface can be removed by washing the film with a suitable solvent. The copolymeric layer typically has a thickness no greater than 500 Angstroms, no greater than 300 Angstroms, no greater than 200 Angstroms, no greater than 100 Angstroms, or no greater than 50 Angstroms.

In some embodiments, the metal-containing surface is patterned. For example, an organic electroluminescent device can have a patterned electrode such as a patterned anode. A coating containing the copolymeric material can be applied as a film to the patterned electrode using a technique such as spin coating. The excess copolymeric material that is not chemically bonded to the patterned electrode can be removed by washing the film with a suitable solvent. The washing can remove any copolymeric material that is not bonded to the patterned electrode. Thus, a patterned layer that contains the copolymeric material can be formed on a patterned electrode. For example, a patterned hole transport layer can be formed on a patterned anode in an organic electroluminescent device.

In some methods, the copolymeric material and the metal-containing substrate can be heated to form a chemical bond. Suitable temperatures depend on the specific group X in Formula I as well as the composition of the substrate. The heat treatment temperature can be up to 200° C., up to 150° C., up to 120° C., up to 110° C., or up to 100° C. When the group X in Formula I is selected from —OP(═O)(OH)₂ or —P(═O)(OH)₂ and the metal-containing substrate includes a metal oxide, a chemical bond often can be formed under ambient conditions (e.g., less than 30° C. such as in the range of 20° C. to 25° C.).

In some methods, the article is an organic electroluminescent device. The method includes providing a first electrode and a second electrode; and positioning an organic emissive element between the first and second electrodes. The organic emissive element includes the copolymeric material having a phosphorous-containing group and a tertiary amino group.

A coating composition containing the copolymeric material can be applied to the first electrode (e.g., anode). A chemical bond can be formed between the surface of the anode and the phosphate or phosphonate groups in the copolymeric material. Further layers can be deposited between copolymeric material and the cathode to provide a multilayer organic emissive element. For example, in some methods, the organic emissive element includes at least a first hole transport layer that include the copolymeric material and a light emitting layer.

The layer containing the copolymeric material can be formed using a solution coating method. The copolymer can be dissolved in a suitable solvent and coated on a substrate using any method known in the art. Coating methods include, for example, spin coating, dip coating, inkjet printing, wiping, and the like.

The resulting thin film tends to be hydrophobic when bonded to an electrode surface and tends to resist dissolution by conventional solvents used in the preparation of organic electroluminescent devices. Additional layers such as light emitting layers or other layers suitable for an organic electroluminescent device can be coated from a solution without adversely affecting a layer previously formed from the copolymeric material. The low erosion of the copolymeric material in subsequent deposition steps can simplify the formation of organic electroluminescent devices.

The foregoing describes the invention in terms of embodiments foreseen by the inventor for which an enabling description was available, notwithstanding that insubstantial modifications of the invention, not presently foreseen, may nonetheless represent equivalents thereto.

### EXAMPLES

All materials were obtained from Aldrich Chemicals unless stated otherwise.

Molecular weight was determined by gel permeation chromatography (GPC) analysis in tetrahydrofuran at room temperature using a Waters 2690 Separation Module from Waters (Medford, Mass.) using Mixed-Bed and 500 Å Separation Columns available from Jordi Associates (Bellingham, Mass.). The molecular weights are based on calibrations with narrow polydispersity polystyrene standards with molecular weights ranging from 580 to 7,500,000 g/mol. M_{w} refers to weight average molecular weight and Mₙ refers to number average molecular weight.

The composition of the copolymers was determined using ¹H and ³¹P NMR spectroscopy. The NMR spectra were obtained on a Varian INOVA 500 NMR spectrometer on solutions of polymeric material dissolved in deuterated chloroform. The cross integration standard was hexamethylphosphoramide (HMP).

### Example 1

### Preparation of poly(styrene-co-p-diphenylaminostyrene-co-diethylvinylphosphate) (PS-pDPAS-DEVP)

The monomer p-diphenylaminostyrene was prepared by a method similar to that described by G. N. Tew, M. U. Pralle and S. I. Stupp, Angew. Chem. Int. Ed., 39, 517 (2000) as follows. More specifically, 80 mL of a 1 mole/liter solution of potassium t-butoxide in tetrahydrofuran (80 mmoles) was added over 5 minutes to a mixture of 4-(diphenylamino)benzaldehyde (20.06 g, 73 mmoles) (available from Fluka Chemicals, Milwaukee, Wis.), methyltriphenylphosphonium bromide (26.22 g, 73 mmoles), and 450 mL dry tetrahydrofuran under nitrogen with stirring. After this addition, the mixture was stirred for 17 hours at room temperature (i.e., 20-25° C.). Water (400 mL) was added and the tetrahydrofuran was removed under reduced pressure. The mixture was extracted with ether, and the combined organic layers were dried over MgSO₄ and concentrated under vacuum. The crude solid was purified by column chromatography on silica gel using a 50/50 mixture of methylene chloride and hexane to give a yellow solid that was further recrystallized once from hexane (15.37 g, 78 percent yield). The composition was confirmed using ¹H NMR and ¹³C NMR.

To prepare the copolymer, a mixture of styrene (3.49 g, 33.7 mmole), p-diphenylaminostyrene (0.5 g, 1.8 mmol), and diethyl vinylphosphonate (0.41 g, 2.4 mmol) was dissolved in ethyl acetate (16 g). Benzoyl peroxide (0.0305 g, 0.126 mmol) was added to this solution. The mixture was sparged with nitrogen for 20 minutes, sealed in a container, and placed in a hot oil bath at 85° C. with stirring for 16 hours. After cooling to room temperature, the copolymer was precipitated from solution by adding the solution slowly to an excess of methanol (200 mL). The resulting solid copolymer was recovered by filtration and dried overnight in a vacuum oven at 40° C. The copolymer was composed of approximately 89.7 mole percent styrene, 9.8 mole percent p-diphenylaminostyrene, and 0.5 mole percent diethyl vinylphosphonate, as determined by ¹H NMR and ³¹P NMR. The copolymer had an M_{w} of 49.2 kg/mol and a polydispersity M_{w}/Mₙ of 5.65.

### Example 2

### Preparation of poly(styrene-co-p-diphenylaminostyrene-co-vinylphosphonic acid) (PS-pDPAS-PV)

Approximately 0.6 g of the copolymer from Example 1 was dissolved in dichloromethane (20 mL) in a round bottomed flask with a rubber septum seal. The solution was sparged with nitrogen for 15 minutes after which bromotrimethylsilane (0.222 mL) was added by syringe. The solution was stirred for 16 hours at room temperature after which the dichloromethane was removed under vacuum. The resulting solid was redissolved in tetrahydrofuran (15 mL) to which methanol (5 mL) was added. After stirring for 3 hours the copolymer was precipitated in methanol (100 mL), redissolved in tetrahydrofuran, and reprecipitated from methanol again. The solid copolymer was subsequently recovered by filtration and dried overnight in a vacuum oven at 40° C. ¹H and ³¹P NMR indicated the complete removal of the ethyl groups, confirming the product as poly(styrene-co-p-diphenylaminostyrene-co-vinylphosphonic acid) (PS-pDPAS-PV).

### Example 3

### Preparation of poly(9-vinylcarbazole-co-p-diphenylaminostyrene-co-diethylphosphonate) (PVK-pDPAS-DEVP)

9-vinylcarbazole (3.21 g, 16.6 mmol), p-diphenylaminostyrene (1.50 g, 5.53 mmol), and diethylvinylphosphonate (0.33 g, 2.0 mmol) were mixed with methyl ethyl ketone (11.56 g). The free radical initiator 2,2′-azobisisobutyronitrile (0.421 g, 0.219 mmol), available from DuPont, Wilmington, Del. under the trade designation “VAZO 67”, was added to this solution. The solution was sparged with nitrogen for 30 minutes, sealed in a container, and heated overnight at 70° C. in an oil bath with stirring. The copolymer was precipitated out of solution by pouring the reaction mixture into methanol (100 mL), after which the precipitate was recovered by filtration and dried in a vacuum oven overnight at 40° C. The resulting copolymer contained 55.3 mole percent p-diphenylaminostyrene, 38.8 mole percent 9-vinylcarbazole, and 5.9 mole percent diethyl vinylphosphonate as determined using ¹H NMR and ³¹P NMR. The M_{w} was 13.3 kg/mol, based upon gel permeation chromatography in tetrahydrofuran using polystyrene molecular weight standards, and a polydispersity M_{w}/Mₙ of 2.12.

### Example 4

### Preparation of poly(9-vinylcarbazole-co-diethyl vinylphosphonate) (PVK-DEVP)

A mixture of 9-vinyl carbazole (3.63 g, 18.8 mmol), diethyl vinylphosphonate (0.14 g, 0.85 mmol), and 2,2′-azobisisobuyronitrile (0.0353 g, 0.18 mmol) were mixed with methyl ethyl ketone (11.99 g). The resulting solution was sparged with nitrogen gas for 20 minutes, sealed in a container, and placed in an oil bath for 20 hours at 80° C. The solution was removed from the oil bath and poured into excess methanol. The resulting precipitate was recovered by vacuum filtration, and subsequently dried in a vacuum oven overnight at room temperature to yield a white powder.

The copolymer, analyzed by a combination of ¹H and ³¹P NMR, contained 94.6 mole percent 9-vinyl carbazole and 5.4 mole percent diethyl vinylphosphonate. This copolymer had a weight-average molecular weight M_{w} of 1.61 kg/mol and a polydispersity M_{w}/Mₙ of 3.63.

### Example 5

### Preparation of poly(9-vinylcarbazole-co-p-diphenylaminostyrene-co-diethyl vinylphosphonate) (PVK-pDPAS-DEVP)

A mixture of 9-vinyl carbazole (3.15 g, 16.3 mmol), diphenylaminostyrene (0.89 g, 3.3 mmol), diethyl vinylphosphonate (0.16 g, 0.97 mmol), and 2,2′-azobisisobuyronitrile (0.0373 g, 0.19 mmol) were mixed with methyl ethyl ketone (12.51 g). The resulting solution was sparged with nitrogen gas for 20 minutes, sealed in a container, and placed in an oil bath for 20 hours at 80° C. The solution was removed from the oil bath and poured into excess methanol. The resulting precipitate was recovered by vacuum filtration, and subsequently dried in a vacuum oven overnight at room temperature to yield a white powder.

The copolymer, analyzed by a combination of ¹³C and ³¹P NMR, contained 53.7 mole percent 9-vinyl carbazole, 38.7 mole percent diphenylaminostyrene, and 7.6 mole percent diethyl vinylphosphonate. The weight-average molecular weight M_{w} for this copolymer was 11.2 kg/mol, with a polydispersity of 2.15.

### Example 6

### Preparation of poly(p-diphenylaminostyrene-co-diethyl vinylphosphonate) (pDPAS-DEVP)

A mixture of p-diphenylaminostyrene (1.10 g, 4.1 mmol), diethyl vinylphosphonate (0.11 g, 0.67 mmol), and 2,2′-azobisisobuyronitrile (0.0227 g, 0.12 mmol) were mixed with methyl ethyl ketone (10.68 g). The resulting solution was sparged with nitrogen gas for 20 minutes, sealed in a container, and placed in an oil bath for 20 hours at 80° C. The solution was removed from the oil bath and poured into excess methanol. The resulting precipitate was recovered by vacuum filtration onto filter paper, and subsequently dried in a vacuum oven overnight at room temperature to yield a white powder.

The copolymer, analyzed by a combination of ¹H and ³¹P NMR, contained 98.7 mole percent p-diphenylaminostyrene and 1.3 mole percent diethyl vinylphosphonate. The weight-average molecular weight M_{w} for this copolymer was 14.3 kg/mol, with a polydispersity of 2.80.

### Example 7

### Preparation of thin films of PS-pDPAS-PV and PVK-pDPAS-DEVP on Glass/Indium Tin Oxide substrates

The films of PS-pDPAS-PV (Example 2) and PVK-pDPAS-DEVP (Example 3) were prepared by spin-coating 0.1-1 weight percent solutions of the copolymers in toluene onto a substrate. The substrates were glass/indium tin oxide obtained from Colorado Concepts Company LLC, Longmont, Colo. The substrates were coated using a spin program having two steps: 30 seconds at 500 RPM, followed by 30 seconds at 2500 RPM. The prepared coatings were subjected to thermal annealing at 150° C. for variable time periods (3-20 minutes) under inert atmosphere, then soaked in toluene and dried to remove all unbound copolymer. Absorption spectra in the ultraviolet and visible regions taken with a HP8453 Spectrophotometer (Hewlett-Packard Company, Palo Alto, Calif.) showed that after this procedure thin films of copolymers formed on the substrate as indicated by absorption bands in the 200-350 nm region.

The stability of the thin copolymer films towards solution processing was further tested by spin-coating dichloroethane on thin film-coated substrates prepared by the afore-mentioned protocol. Subsequent spectroscopic analysis in the ultraviolet and visible regions indicated that absorption bands in the 200-350 nm region corresponding to PS-pDPAS-PV and PVK-pDPAS-DEVP thin films retain their original intensities, which confirms stability of the thin copolymer films towards further solution processing.

### Example 8

### Preparation of Organic Light-emitting Diodes (OLEDs)

Films of PS-pDPAS-PV and PVK-pDPAS-DEPV were coated on glass/indium tin oxide substrates (Colorado Concepts Company LLC, Longmont, Colo.) as described in Example 7 using a 0.1 weight percent solution of each copolymer in toluene. The prepared films were then annealed at 150° C. for 5 minutes.

An aqueous dispersion of poly(3,4-ethylene dioxythiophene)/polystyrenesulfonate (PEDT/PSS) was obtained from H. C. Starck, Newton, Mass. under the trade designation “BAYTRONP VP CH 8000”. The aqueous dispersion was filtered through a 0.2 micrometer nylon filter. PEDT/PSS films having a thickness of 500 Å were prepared by spin-coating the aqueous dispersion at 2000 RPM for 40 seconds, followed by thermal annealing of the films at 120° C. for 10 minutes under an inert atmosphere.

OLED constructions were made from each sample by vacuum depositing 200 Å N,N′-bis(1-naphtyl)-N,N′-bis(phenyl)benzidine (NPB); 300 Å aluminum tris(8-hydroxyquinolato) (Alq3) doped with the fluorescent coumarin dye 10-(2-benzothiazolyl)-2,3,6,7-tetrahydro-1,1,7,7,-tetramethyl-1H,5H,11H-[1]benzopyrano[6,7,8-ij]quinolizin-11-one (C545T, available from H. W. Sands, Jupiter, Fla.) at 1 weight percent concentration; and 200 Å of undoped Alq3 in that order on each film respectively. A control device was constructed by vacuum deposition of these layers on bare ITO. The devices were each capped with a LiF (10 Å)/Al (2000 Å) cathode deposited through a 1 cm² square shadow mask. The vacuum depositions were done at 10⁻⁵-10⁻⁶ Torr.

Light output—current—voltage (LIV) characteristics of the resulting OLEDs driven by a DC current sweep in 0-20 mA/cm² current density range were measured using a Keithley Model 2400 SOURCEMETER (available from Keithley Instruments, Inc., Cleveland, Ohio). The data is summarized in Table 1.

TABLE 1
Device Testing

| | Device | External quantum | Voltage at |
|---|---|---|---|
| | yield, | efficiency at | 4 mA/cm², |
| Device type | % | 4 mA/cm², % | V |
| ITO/NPB/Alq:C545T/ | 50 | 2.2 ± 0.2 | 5.0 ± 0.2 |
| Alq/LiF/Al | | | |
| ITO/PEDT:PSS/ | 100 | 2.2 ± 0.2 | 4.8 ± 0.2 |
| NPB/Alq:C545T/ | | | |
| Alq/LiF/Al | | | |
| ITO/PS-pDPAS- | 80-90 | 2.5 ± 0.2 | 5.5 ± 0.2 |
| PV/NPB/Alq:C545T/ | | | |
| Alq/LiF/Al | | | |
| ITO/PVK-pDPAS- | 80-90 | 2.3 ± 0.3 | 5.2 ± 0.2 |
| DEPV/NPB/Alq:C545T/ | | | |
| Alq/LiF/Al | | | |

The device yield is defined as yield of non short-circuited devices, i.e. ratio of non short-circuited devices to the total number of the devices in the category. At least 50 percent of control electroluminescent devices prepared on bare ITO substrates had short-circuits as indicated by no detected electroluminescence and abnormally small voltage readings during their LIV sweeps. This can be attributed to initial ITO roughness.

Deposition of a PEDT/PSS layer on top of ITO completely eliminates the short-circuiting problem, but the drawback of using waterborne PEDT/PSS as a layer in OLEDs is that it is hygroscopic and its uptake of water reduces device operation stability. The devices made on top of PS-pDPAS-PV, and PVK-pDPAS-DEPV layer films with thicknesses of less than 100 Å had less than 5-10 percent short-circuited areas and showed LIV characteristics very similar to those of PEDT/PSS devices, i.e. high electroluminescence efficiency and low operation voltage.

We claim:

1. A copolymer comprising the reaction product of a monomer mixture comprising:
a) a first ethylenically unsaturated monomer having a phosphate group of formula —OP(═O)(OR²)₂ or a phosphonate group —P(═O)(OR²)₂, wherein each R² is independently hydrogen, alkyl, aryl, or aralkyl; and
b) a second ethylenically unsaturated monomer having tertiary amino group selected from an triarylamino group or a carbazolyl group.

2. The copolymer of claim 1, wherein the first ethylenically unsaturated monomer is of Formula I: 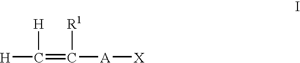
wherein
R¹ is hydrogen or alkyl;
X is a phosphonate of formula —P(═O)(OR²)₂ or a phosphate of formula —OP(═O)(OR²)₂ where each R² is independently hydrogen, alkyl, aryl, or aralkyl; and
A is a divalent linking group of formula -Q- or of formula —C(═O)OQ-, where Q is a single bond, alkylene, heteroalkylene, arylene, or a combination thereof, said Q being unsubstituted or substituted with a hydroxy, alkoxy, alkyl, halo, haloalkyl, or combination thereof.

3. The copolymer of claim 2, wherein A is of formula —C(═O)OQ- and R¹ is hydrogen or methyl.

4. The copolymer of claim 2, wherein the first monomer is a methacrylate monomer selected from 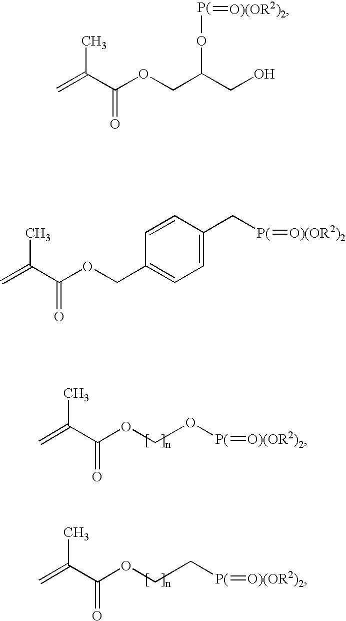
or a combination thereof, where n is an integer of 1 to 20.

5. The copolymer of claim 2, wherein the first ethylenically unsaturated monomer is of a vinyl monomer of formula

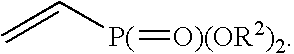

6. The copolymer of claim 5, wherein the first ethylenically unsaturated monomer is vinylphosphonic acid or diethyl vinylphosphonate.

7. The copolymer of claim 2, wherein the first ethylenically unsaturated monomer is a styrene monomer of formula

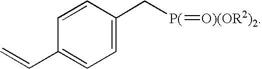

8. The copolymer of claim 1, wherein the second ethylenically unsaturated monomer has a carbozolyl group.

9. The copolymer of claim 8, wherein the second ethylenically unsaturated monomer is selected from 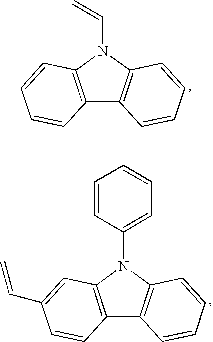
or a combination thereof, where an aryl group can be unsubstituted or substituted with a diarylamino, triarylamino, alkyl, alkoxy, halo, haloalkyl, hydroxy, or combination thereof.

10. The copolymer of claim 1, wherein the second ethylenically unsaturated monomer is of Formula IV: 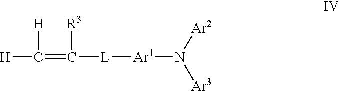
where
R³ is hydrogen or an alkyl;
L is a divalent linking group selected from single bond, carbonyloxy, alkylene, heteroalkylene, arylene, or a combination thereof
Ar¹ is an arylene that is unsubstituted or substituted with a diarylamino, triarylamino, alkyl, alkoxy, halo, haloalkyl, hydroxy, or combination thereof; and
Ar² and Ar³ are each independently an aryl that is unsubstituted or substituted with a diarylamino, triarylamino, alkyl, alkoxy, halo, haloalkyl, hydroxy, or combination thereof; or
Ar², Ar³, and a nitrogen atom to which both Ar2 and Ar3 are both attached combine to form a fused aromatic group that is unsubstituted or substituted with a diarylamino, triarylamino, alkyl, alkoxy, halo, haloalkyl, hydroxy, or combination thereof.

11. The copolymer of claim 10, wherein the Ar¹, Ar², and Ar³ are independently selected from phenylene, biphenylene, naphthalene, or fluorene.

12. The copolymer of claim 10, wherein Ar², Ar³, and the nitrogen to which they are attached combine to form a carbozolyl group.

13. The copolymer of claim 10, wherein L is selected from a single bond, —C(═O)—, —C(═O)J-, or —Ar⁴J- where J is an alkylene or heteroalkylene and where Ar⁴ is an arylene.

14. The copolymer of claim 10, wherein the monomer of Formula II is selected from

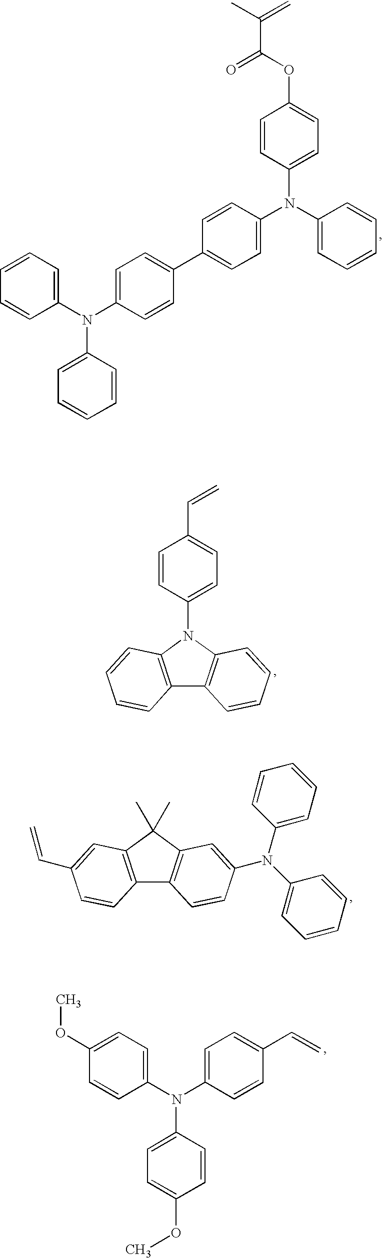

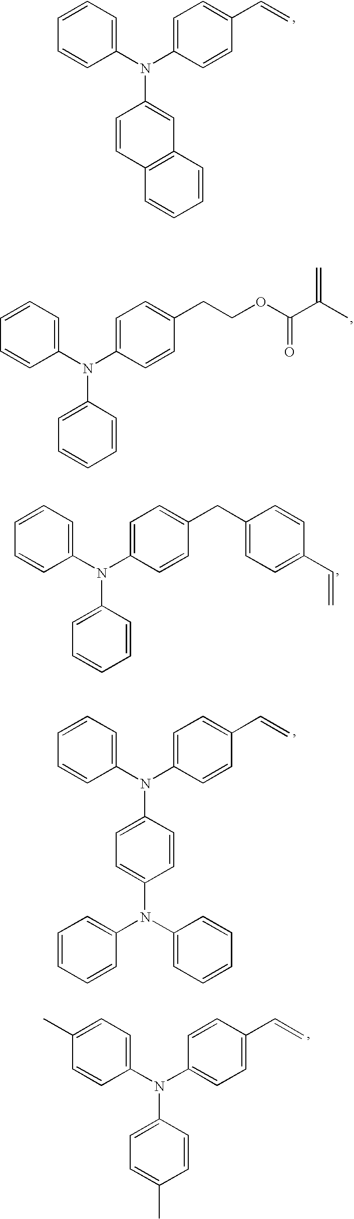

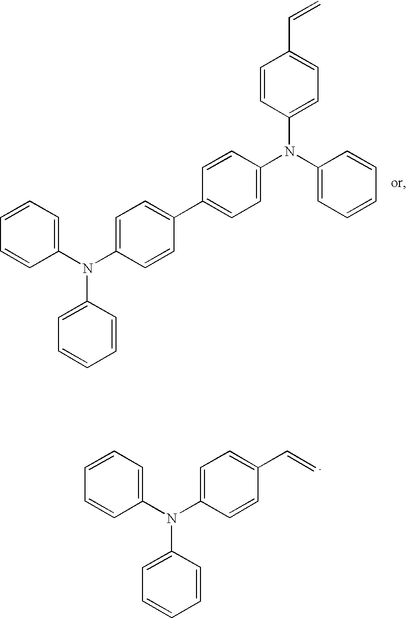

15. The copolymer of claim 1, wherein the monomer mixture contains no more than 20 mole percent of the first ethylenically unsaturated monomer.

16. An article comprising:
a) a metal-containing surface; and
b) a copolymeric material chemically bonded to the metal-containing surface, said copolymeric material comprising the reaction product of a monomer mixture comprising:
i) a first ethylenically unsaturated monomer having a phosphate group of formula —OP(═O)(OR²)₂ or a phosphonate group of formula —P(═O)(OR²)₂, wherein each R² is independently hydrogen, alkyl, aryl, or aralkyl; and
ii) a second ethylenically unsaturated monomer having tertiary amino group selected from an triarylamino group or a carbazolyl group.

17. An organic electroluminescent device comprising:
a) a first electrode and a second electrode; and
b) an organic emissive element positioned between the first and second electrodes, the organic emissive element comprising a copolymeric material comprising the reaction product of a monomer mixture comprising:
i) a first ethylenically unsaturated monomer having a phosphate group of formula —OP(═O)(OR²)₂ or a phosphonate group of formula —P(═O)(OR²)₂, wherein each R² is independently hydrogen, alkyl, aryl, or aralkyl; and
ii) a second ethylenically unsaturated monomer having tertiary amino group selected from an triarylamino group or a carbazolyl group.

18. The organic electroluminescent device of claim 17, wherein the copolymeric material is chemically bonded to a surface of the first electrode.

19. The organic electroluminescent device of claim 17, wherein the organic emissive element comprises a hole transport layer comprising the copolymeric material.

20. A method of making an organic electroluminescent device comprising:
providing a first electrode and a second electrode;
positioning an organic emissive element between the first electrode and the second electrode, wherein the organic emissive element comprises a copolymeric material comprising the reaction product of a monomer mixture comprising:
a) a first ethylenically unsaturated monomer having a phosphate group of formula OP(═O)(OR²)₂ or a phosphonate group of formula —P(═O)(OR²)₂, wherein each R² is independently hydrogen, alkyl, aryl, or aralkyl; and
b) a second ethylenically unsaturated monomer having tertiary amino group selected from an triarylamino group or a carbazolyl group.
